(19) United States
(12) Patent Application Publication
(10) Pub. No.: US 2021/0087684 A1
(43) Pub. Date: Mar. 25, 2021

(54) DEPOSITION APPARATUS AND DEPOSITION METHOD

(71) Applicant: Tokyo Electron Limited, Tokyo (JP)

(72) Inventors: Yu SASAKI, Iwate (JP); Toshihiko JO, Yamanashi (JP); Hitoshi KATO, Iwate (JP); Kosuke TAKAHASHI, Iwate (JP)

(21) Appl. No.: 17/016,590

(22) Filed: Sep. 10, 2020

(30) Foreign Application Priority Data
Sep. 24, 2019 (JP) 2019-173447

(51) Int. Cl. C23C 16/455; C23C 16/458

(52) U.S. Cl. CPC C23C 16/45544; C23C 16/4584

(57) ABSTRACT

A deposition apparatus according to one aspect of the present disclosure includes a processing chamber and a rotary table provided in the processing chamber. Above the rotary table, a raw material gas supply section, auxiliary gas supply sections, and a gas exhaust section are provided. The raw material gas supply section extends in a radial direction of the rotary table. The auxiliary gas supply sections are provided on a downstream side of a rotational direction of the rotary table with respect to the raw material gas supply section, and are arranged in the radial direction of the rotary table. The gas exhaust section is provided on the downstream side of the rotational direction of the rotary table with respect to the auxiliary gas supply sections, and extends in the radial direction of the rotary table.

### CROSS-REFERENCE TO RELATED APPLICATIONS

This patent application is based upon and claims priority to Japanese Patent Application No. 2019-173447 filed on Sep. 24, 2019, the entire contents of which are incorporated herein by reference.

### TECHNICAL FIELD

The present disclosure relates to a deposition apparatus and a deposition method.

### BACKGROUND

A rotary table-type atomic layer deposition (ALD) device is known, in which a rotary table including substrate mounting regions for placing substrates along a circumferential direction is rotated, to cause the substrates to pass through multiple processing regions, thereby forming a film (see Patent Document 1, for example). In the ALD device, at least one of the multiple processing regions is provided with an exhaust member formed of a hollow body, which covers an exhaust port provided at a position outside the periphery of the rotary table, and which extends from the outer edge of the substrate mounting region to the inner edge of the substrate mounting region.

### RELATED ART DOCUMENT

### Patent Document

[Patent Document 1] Japanese Laid-open Patent Application Publication No. 2013-042008

### SUMMARY

The present disclosure provides a technique for adjusting in-plane distribution of film thickness with high accuracy.

A deposition apparatus according to one aspect of the present disclosure includes a processing chamber and a rotary table provided in the processing chamber. Above the rotary table, a raw material gas supply section, auxiliary gas supply sections, and a gas exhaust section are provided. The raw material gas supply section extends in a radial direction of the rotary table. The auxiliary gas supply sections are provided on a downstream side of a rotational direction of the rotary table with respect to the raw material gas supply section, and are arranged in the radial direction of the rotary table. The gas exhaust section is provided on the downstream side of the rotational direction of the rotary table with respect to the auxiliary gas supply sections, and extends in the radial direction of the rotary table.

### BRIEF DESCRIPTION OF THE DRAWINGS

FIG. 1 is a cross-sectional view illustrating an example of the configuration of a deposition apparatus according to a first embodiment;

FIG. 2 is a perspective view illustrating the configuration of the interior of a vacuum vessel in the deposition apparatus of FIG. 1;

FIG. 3 is a plan view illustrating the configuration of the interior of the vacuum vessel in the deposition apparatus of FIG. 1;

FIG. 4 is a cross-sectional view of the vacuum vessel along a concentric circle of a rotary table rotatably provided in the vacuum vessel of the deposition apparatus of FIG. 1;

FIG. 5 is another cross-sectional view of the deposition apparatus of FIG. 1;

FIG. 6 is a top view of a showerhead of the deposition apparatus of FIG. 1;

FIG. 7 is a cross-sectional view of the showerhead of the deposition apparatus of FIG. 1;

FIG. 8 is a diagram illustrating an example of the overall configuration of the showerhead of the deposition apparatus of FIG. 1;

FIG. 9 is a cross-sectional perspective view of the showerhead of the deposition apparatus of FIG. 1, which is cut along a raw material gas supply section;

FIG. 10 is a cross-sectional view illustrating an example of the configuration of a deposition apparatus according to a second embodiment;

FIGS. 11A to 11C are diagrams for explaining film thickness distribution for each gas species;

FIGS. 12A and 12B are diagrams illustrating analysis results of simulation experiments 1-1 and 1-2;

FIGS. 13A to 13C are diagrams illustrating analysis results of simulation experiments 2-1, 2-2, 3-1, 3-2, 4-1, and 4-2; and

FIG. 14 is a diagram illustrating another analysis result of the simulation experiments 2-1, 2-2, 3-1, 3-2, 4-1, and 4-2.

### DETAILED DESCRIPTION OF EMBODIMENTS

Hereinafter, non-limiting example embodiments of the present disclosure will be described with reference to the accompanying drawings. In all the accompanying drawings, the same or corresponding reference numerals shall be attached to the same or corresponding components and overlapping descriptions may be omitted.

### First Embodiments

### (Deposition Apparatus)

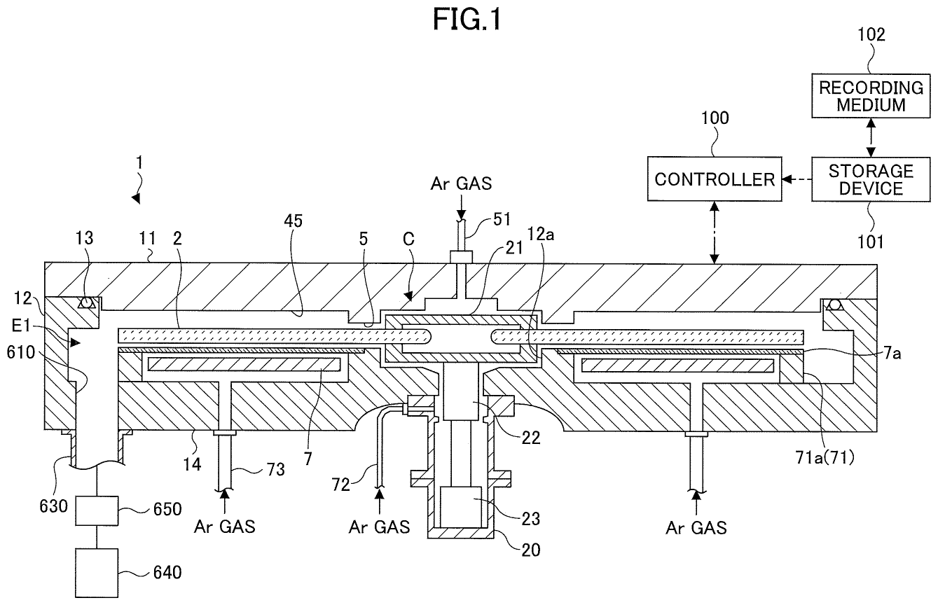

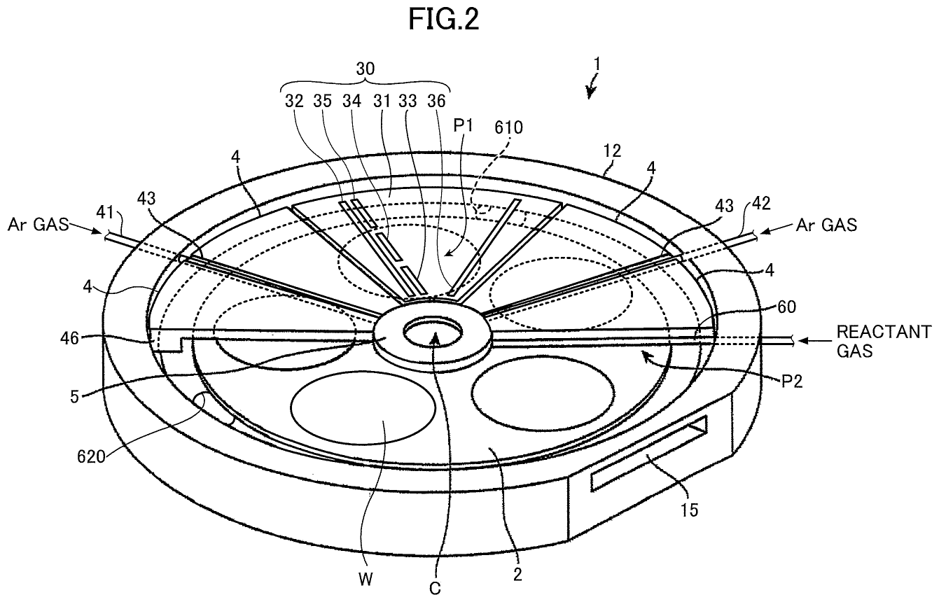

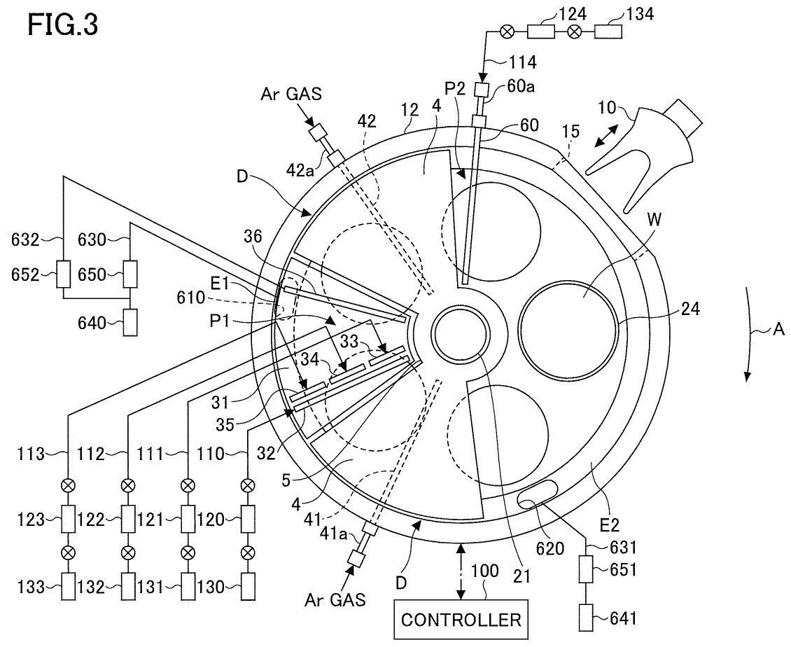

A deposition apparatus according to a first embodiment will be described. FIG. 1 is a cross-sectional view illustrating an example of the configuration of the deposition apparatus according to the first embodiment. FIGS. 2 and 3 are perspective and plan views, respectively, illustrating the configuration of the interior of a vacuum vessel 1 provided in the deposition apparatus of FIG. 1. In FIGS. 2 and 3, illustration of a top plate 11 is omitted.

Referring to FIGS. 1 through 3, the deposition apparatus includes a flat vacuum vessel 1 having a substantially circular planar shape, and a rotary table 2 disposed within the vacuum vessel 1. The rotary table 2 has a rotational center at the center of the vacuum vessel 1, in a plan view. The vacuum vessel 1 is a processing chamber in which a substrate to be processed, such as a semiconductor wafer (hereinafter, referred to as a “wafer W”) is loaded and a deposition process is applied to the wafer W.

The vacuum vessel 1 includes a cylindrical container, body 12 having a bottom, and a removable top plate 11. The top plate 11 is disposed on the upper surface of the container body 12 in an airtight manner via a sealing member 13 such as an O-ring (FIG. 1).

The center of the rotary table 2 is fixed to a cylindrical core 21. The core 21 is secured to the upper end of a rotating shaft 22 (FIG. 1) extending vertically. The rotating shaft 22 penetrates the bottom 14 of the vacuum vessel 1, and the lower end of the rotating shaft 22 is attached to a drive section 23 that rotates the rotating shaft 22 about a vertical axis. The rotating shaft 22 and the drive section 23 are stored in a cylindrical casing 20 having an open upper surface. A flange is provided on the upper surface of the casing 20. The flange is hermetically attached to the lower surface of the bottom 14 of the vacuum vessel 1. Thus, the internal atmosphere of the casing 20 is separated from an external atmosphere, and is maintained in an airtight condition.

As Illustrated In FIGS. 2 and 3, on the upper surface of the rotary table 2, multiple circular recesses 24 (five recesses in the illustrated example) are provided along the rotational direction (the circumferential direction) of the rotary table 2. In each of the recesses 24, a wafer W can be placed. For convenience, a case in which a wafer W is placed in only one of the recesses 24 is illustrated in FIG. 3. The recess 24 has an inner diameter that, is slightly greater (greater by 4 mm, for example) than a diameter of a wafer W, and has a depth approximately equal to a thickness of a wafer W. Therefore, when a wafer W is placed in the recess 24, the surface of the wafer W and the surface of the rotary table 2 (an area on which the wafer W is not placed) become the same height. At the bottom surface of the recess 24, through-holes (not illustrated) are formed, through which, for example, three lift pins penetrate to support the back surface of a wafer W and to raise and lower the wafer W.

Above the rotary table 2, a bottom plate 31 of a showerhead 30, a processing gas nozzle 60, and separation gas nozzles 41 and 42 are arranged at intervals, in a circumferential direction of the vacuum vessel 1, that is, in the rotational direction of the rotary table 2 (see the arrow A of FIG. 3). In the example illustrated in FIG. 3, the separation gas nozzle 41, the bottom plate 31, the separation gas nozzle 42, and the processing gas nozzle 60 are arranged in this order clockwise (rotational direction of the rotary table 2), from a conveying port 15 to be described below.

In the bottom plate 31 of the showerhead 30, a raw material gas supply section 32, an axial-side auxiliary gas supply section 33, an intermediate auxiliary gas supply section 34, an outer-side auxiliary gas supply section 35, and a gas exhaust section 36 are formed. The raw material gas supply section 32, the axial-side auxiliary gas supply section 33, the intermediate auxiliary gas supply section 34, and the outer-side auxiliary gas supply section 35 supply a raw material gas, an axial-side auxiliary gas, an intermediate auxiliary gas, and an outer-side auxiliary gas, respectively. Hereinafter, the axial-side auxiliary gas, the intermediate auxiliary gas, and the outer-side auxiliary gas are collectively referred to as an auxiliary gas. Also, the axial-side auxiliary gas supply section 33, the intermediate auxiliary gas supply section 34, and the outer-side auxiliary gas supply section 35 are collectively referred to as an auxiliary gas supply section. The axial-side auxiliary gas supply section 33, the intermediate auxiliary gas supply section 34, and the outer-side auxiliary gas supply section 35 are arranged linearly along the radial direction of the rotary table 2 at regular intervals.

Multiple gas discharge holes (not illustrated) are formed on the bottom surface of each of the raw material gas supply section 32, the axial-side auxiliary gas supply section 33, the intermediate auxiliary gas supply section 34, and the outer-side auxiliary gas supply section 35, to supply the raw material gas and the auxiliary gas along the radial direction of the rotary table 2. On the bottom surface of each of the raw material gas supply section 32, the axial-side auxiliary gas supply section 33, the intermediate auxiliary gas supply section 34, and the outer-side auxiliary gas supply section 35, the multiple gas discharge holes are arranged linearly along the radial direction of the rotary table 2.

The raw material gas supply section 32 extends radially throughout the radius of the rotary table 2 to cover the entire wafer W. The axial-side auxiliary gas supply section 33 extends only in a predetermined area on the axial side (i.e., closer to the axis of the rotary table 2) of the rotary table 2, along the radial direction of the rotary table 2, and the size of the predetermined area is approximately one-third of the raw material gas supply section 32. The intermediate auxiliary gas supply section 34 extends, along the radial direction of the rotary table 2, only in a predetermined area having a size of approximately one-third of the raw material gas supply section 32, between the axial side and the outer peripheral side of the rotary table Z. The outer-side auxiliary gas supply section 35 extends, along the radial direction of the rotary table 2, only in a predetermined area having a size of approximately one-third of the raw material gas supply section 32, on the outer peripheral side of the rotary table 2.

The raw material gas supply section 32, the axial-side auxiliary gas supply section 33, the intermediate auxiliary gas supply section 34, and the outer-side auxiliary gas supply section 35 are provided at the bottom plate 31 of the showerhead 30. Therefore, the raw material gas and the auxiliary gas introduced into the showerhead 30 are introduced into the vacuum vessel 1 via the raw material gas supply section 32, the axial-side auxiliary gas supply section 33, the intermediate auxiliary gas supply section 34, and the outer-side auxiliary gas supply section 35.

The raw material gas supply section 32 is connected to a raw material gas source 130 via a pipe 110, a flow controller 120, and the like. The axial-side auxiliary gas supply section 33 is connected to an axial-side auxiliary gas source 131 via a pipe 111, a flow controller 121, and the like. The intermediate auxiliary gas supply section 34 is connected to an intermediate auxiliary gas source 132 via a pipe 112, a flow controller 122, and the like. The outer-side auxiliary gas supply section 35 is connected to an outer-side auxiliary gas supply 133 through a pipe 113, a flow controller 123, and the like. The raw material gas may be a silicon-containing gas such as organic aminosilane gas, or may be a titanium-containing gas such as TiCl₄. The axial-side auxiliary gas, the intermediate side auxiliary gas, and the outer-side auxiliary gas may be, for example, a noble gas such as Ar, an inert gas such as nitrogen gas, the same gas as the raw material gas, a mixture of these gases, or any other types of gas. Gas that is suitable for, for example, improving in-plane uniformity or adjusting film thickness, is selected as the auxiliary gas, depending on its application and process.

In the illustrated example, the gas sources 130 to 133 are respectively connected to the raw material gas supply section 32, the axial-side auxiliary gas supply section 33, the intermediate auxiliary gas supply section 34, and the outer-side auxiliary gas supply section 35, in a one-to-one configuration. That is, for each of the raw material gas supply section 32, the axial-side auxiliary gas supply section 33, the intermediate auxiliary gas supply section 34, and the outer-side auxiliary gas supply section 35, a flow rate and composition of gas supplied can be controlled independently. However, a configuration of the gas sources 130 to 133, the raw material gas supply section 32, the axial-side auxiliary gas supply section 33, the intermediate auxiliary gas supply section 34, and the outer-side auxiliary gas supply section 35 are not limited to the configuration in the illustrated example. For example, in a case in which a mixed gas is supplied, pipes may be further added to connect gas supply lines with each other, to supply a gas of an appropriate mixture ratio to the raw material gas supply section 32, the axial-side auxiliary gas supply section 33, the intermediate auxiliary gas supply section 34, and the outer-side auxiliary gas supply section 35 individually. That is, when supplying a mixed gas to the raw material gas supply section 32, the axial-side auxiliary gas supply section 33, the intermediate auxiliary gas supply section 34, and the outer-side auxiliary gas supply section 35, a raw material gas, an axial-side auxiliary gas, an intermediate side auxiliary gas, and an outer-side auxiliary gas may be supplied from the raw material gas source 130, the axial-side auxiliary gas source 131, the intermediate auxiliary gas source 132, and the outer-side auxiliary gas supply 133 respectively, and these gases may be mixed through the pipes connecting between gas supply lines of the raw material gas source 130, the axial-side auxiliary gas source 131, the intermediate auxiliary gas source 132, and the outer-side auxiliary gas supply 133, to supply a mixed gas to the raw material gas supply section 32, the axial-side auxiliary gas supply section 33, the intermediate auxiliary gas supply section 34, and the outer-side auxiliary gas supply section 35. That is, as long as a gas can ultimately be supplied to each of the raw material gas supply section 32, the axial-side auxiliary gas supply section 33, the intermediate auxiliary gas supply section 34, and the outer-side auxiliary gas supply section 35 individually, a connection structure of the intermediate gas supply passage does not matter.

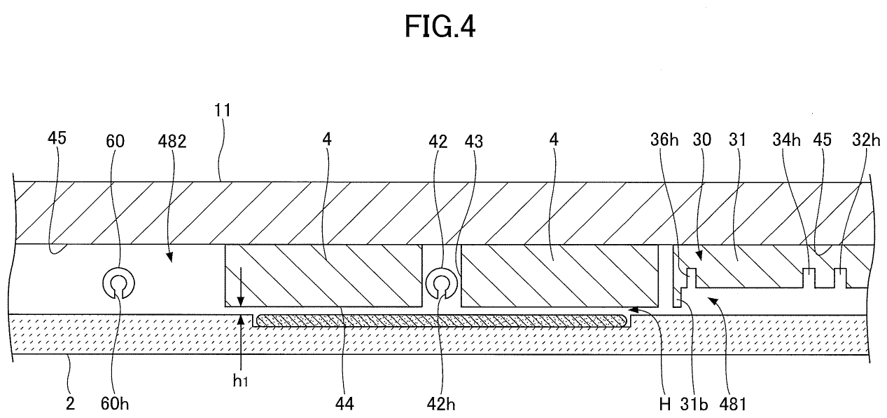

The gas exhaust section 36 extends throughout the radius of the rotary table 2 to cover the entire wafer W. One or more gas exhaust holes 36h (FIG. 4) are formed on the bottom surface of the gas exhaust section 36 to exhaust the raw material gas and the auxiliary gas along the radial direction of the rotary table 2. The distance between the gas exhaust section 36 and the rotary table 2 is formed to be the same as, for example, the distance between the axial-side auxiliary gas supply section 33 and the rotary table 2, the intermediate auxiliary gas supply section 34 and the rotary table 2, or the outer-side auxiliary gas supply section 35 and the rotary table 2.

The gas exhaust section 36 is connected to a vacuum evacuation means such as a vacuum pump 640, via an exhaust pipe 632 that is provided between the gas exhaust section 36 and the vacuum pump 640. Also, a pressure controller 652 is provided in the exhaust pipe 632. Accordingly, exhaust pressure of the gas exhaust section 36 is controlled independently of exhaust pressure of a first exhaust port 610, which will be described below. The pressure controller 652 may be, for example, an automatic pressure controller (APC).

The processing gas nozzle 60 and the separation gas nozzles 41 and 42 are each formed of, for example, quartz. The processing gas nozzle 60 is introduced into the vacuum vessel 1 from the outer peripheral wall of the vacuum vessel 1 along the radial direction of the container body 12, and is mounted horizontally with respect to the rotary table 2 by fixing a gas inlet port 60a, which is an end of the processing gas nozzle 60, to the outer peripheral wall of the container body 12. The separation gas nozzles 41 and 42 are introduced into the vacuum vessel 1 from the outer peripheral wall of the vacuum vessel 1 along the radial direction of the container body 12, and are mounted horizontally with respect to the rotary table 2 by fixing gas inlet ports 41a and 42a, which are ends of the separation gas nozzles 41 and 42 respectively, to the outer peripheral wall of the container body 12.

The processing gas nozzle 60 is connected to a reactant gas supply source 134, via a pipe 114, a flow controller 124, and the like. A gas that reacts with the raw material gas to produce a reaction product is referred to as a reactant gas. For example, an oxidant gas such as ozone (O₃) is a reactant gas with respect to a silicon-containing gas, and a nitriding gas such as ammonia (NH₃) is a reactant gas with respect to a titanium-containing gas. In the processing gas nozzle 60, multiple gas discharge holes 60h (FIG. 4) that open toward the rotary table 2 are arranged along a longitudinal direction of the processing gas nozzle 60, at intervals of 10 mm, for example.

Both the separation gas nozzles 41 and 42 are connected to a separation gas source (not illustrated) via a pipe, a flow control valve, and the like, neither of which are illustrated in the drawings. As a separation gas, a noble gas such as helium (He) or argon (Ar), or an inert gas such as nitrogen (N₂) gas may be used. In the present embodiment, a case in which Ar gas is used will be described.

A region below the bottom plate 31 of the showerhead 30 is referred to as a first processing region P1, in which the wafer W is caused to adsorb a raw material gas. A region below the processing gas nozzle 60 is referred to as a second processing region P2, in which a reactant gas that reacts with the raw material gas adsorbed on the wafer W is supplied, and in which a molecular layer of a reaction product is produced. The molecular layer of the reaction product constitutes a film to be deposited. The first processing region P1 is also referred to as a raw material gas supply region because a raw material gas is supplied in the first processing region P1. The second processing region P2 is also referred to as a reactant gas supply region because a reactant gas, capable of producing a reaction product by reacting with a raw material gas, is supplied in the second processing region P2.

Referring again to FIGS. 2 and 3, two projections 4 are provided in the vacuum vessel 1. The projections 4 are attached to the back surface of the top plate 11 so as to protrude toward the rotary table 2, in order to form separation regions D with the separation gas nozzles 41 and 42. Each of the projections 4 has a fan-shaped plane, an apex of which is cut in a shape of an arc. In the present embodiment, an inner arc-shaped portion of the projection 4 is connected to the protruding portion 5 (described below) and an outer arc of the projection 4 is disposed along the inner peripheral surface of the container body 12 of the vacuum vessel 1.

FIG. 4 illustrates a cross-section of the vacuum vessel 1 along a concentric circle of the rotary table 2 from the bottom plate 31 of the showerhead 30 to the processing gas nozzle 60. As illustrated, the projection 4 is attached to the back surface of the top plate 11. Therefore, within the vacuum vessel 1, first ceiling surfaces 44 having flat and low ceiling surfaces, and second ceiling surfaces 46 are present. The first ceiling surfaces 44 correspond to lower surfaces of the projections 4, and the second ceiling surfaces 45 are higher than the first ceiling surfaces 44. At both sides of the first ceiling surfaces 44 in a circumferential direction, the second ceiling surfaces 45 are provided. The first ceiling surface 44 has a fan-shaped plane, an apex of which is cut in a shape of an arc. As illustrated in FIG. 4, at the center of one of the projections 4 in the circumferential direction, a groove 43 that extends radially is formed, and the groove 43 accommodates the separation gas nozzle 42. Although FIG. 4 illustrates only one of the projections 4, the groove 43 is formed in the other projection 4 similarly, and the separation gas nozzle 41 is stored in the groove 43 of the other projection 4. Further, the bottom plate 31 of the showerhead 30 and the processing gas nozzle 60 are provided in spaces (431 and 482) under the second ceiling surfaces 45. The processing gas nozzle 60 is provided at a position spaced apart from the second ceiling surface 45, so as to be positioned near the wafer W. As illustrated in FIG. 4, the bottom plate 31 is provided in the space 481 on the right, side of the projection 4, and the processing gas nozzle 60 is provided in the space 482 on the left side of the projection 4.

Multiple gas discharge holes 42h (FIG. 4) that open toward the rotary table 2 are arranged on the separation gas nozzle 42 stored in the groove 43 of the one of the projections 4 at intervals of, for example, 10 mm, in a longitudinal direction of the separation gas nozzle 42. Similarly, on the separation gas nozzle 41 stored in the groove 43 of the other one of the projections 4, multiple gas discharge holes 41h (not illustrated) that open toward the rotary table 2 are arranged in a longitudinal direction of the separation gas nozzle 41, for example, at intervals of 10 mm.

The raw material gas supply section 32, the axial-side auxiliary gas supply section 33, the intermediate auxiliary gas supply section 34, and the outer-side auxiliary gas supply section 35 provided at the bottom plate 31 of the showerhead 30 have gas discharge holes 32h, 33h (not illustrated in FIG. 4), 34h, and 35h (not illustrated in FIG. 4), respectively. As illustrated in FIG. 4, the gas discharge holes 32h are provided at approximately the same height as the gas discharge holes 60h of the processing gas nozzle 60 and the gas discharge holes 42h of the separation gas nozzle 42. Further, the gas discharge holes 33h, 34h, and 35h are provided at the same height as the gas discharge holes 60h of the processing gas nozzle 60 and the gas discharge holes 42h of the separation gas nozzle 42, similarly to the gas discharge holes 32h.

However, the distances between the rotary table 2 and the axial-side auxiliary gas supply section 33 between the rotary table 2 and the intermediate auxiliary gas supply section 34, and between the rotary table 2 and the outer-side auxiliary gas supply section 35, may be different from the distance between the raw material gas supply section 32 and the rotary table 2.

In addition, the heights of the axial-side auxiliary gas supply section 33, the intermediate auxiliary gas supply section 34, and the outer-side auxiliary gas supply section 35 need not be the same and may be different.

The gas exhaust section 36 provided at the bottom plate 31 of the showerhead 30 has the gas exhaust holes 36h, as illustrated in FIG. 4. The gas exhaust holes 36h of the gas exhaust section 36 are provided at approximately the same height as the gas discharge holes 35h of the outer-side auxiliary gas supply section 35.

The first ceiling surface 44 forms a narrow space between the rotary table 2 and the first ceiling surface 44. The narrow space formed by the first ceiling surface 44 may also be referred to as a “separation space H”. When Ar gas is supplied from the gas discharge holes 42h of the separation gas nozzle 42, the Ar gas flows toward the spaces 481 and 482 through the separation space H. As the volume of the separation space H is smaller than the volumes of the spaces 481 and 432, pressure in the separation space H can be increased by the Ar gas as compared to pressures in the spaces 481 and 482. That is, between the spaces 481 and 482, the separation space H of high pressure is formed. The Ar gas flowing from the separation space H into the spaces 481 and 482 also acts as a counterflow against the raw material gas from the first processing region P1 and the reactant gas from the second processing region P2. Therefore, the raw material gas from the first processing region P1 and the reactant gas from the second processing region P2 are separated by the separation space H. Therefore, mixing and reacting of the raw material gas and the reactant gas in the vacuum vessel 1 is suppressed.

The height h1 of the first ceiling surface 44 relative to the upper surface of the rotary table 2 is set to a height suitable for making the pressure in the separating space H higher than the pressures in the spaces 481 and 482, in consideration of a pressure in the vacuum vessel 1 during deposition, rotating speed of the rotary table 2 during deposition, a flow rate of the separation gas supplied during deposition, and the like.

Meanwhile, on the back surface of the top plate 11, a protruding portion 5 (FIGS. 2 and 3) that surrounds the outer circumference of the core 21 that fixes the rotary table 2 is provided. In the present embodiment, the protruding portion 5 is continuous with a portion of the projection 4 on the rotational center side, and the lower surface of the protruding portion 5 is formed at the same height as the first ceiling surface 44.

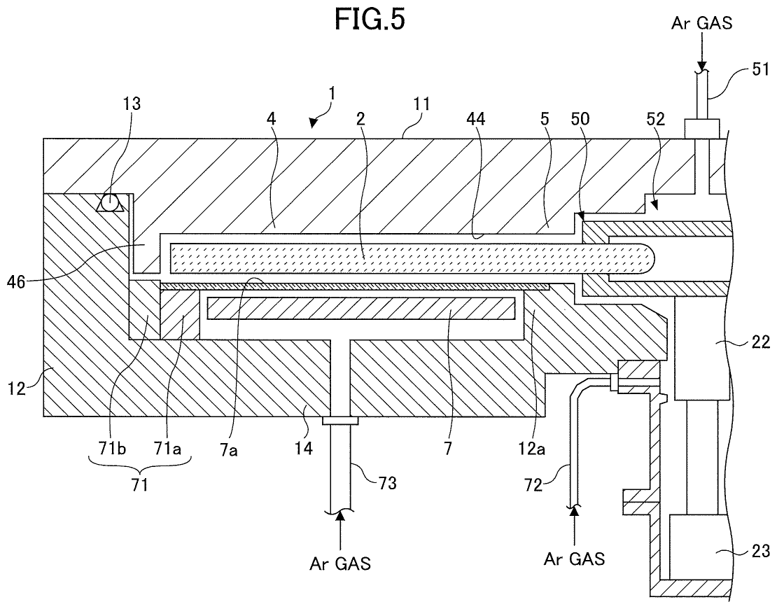

FIG. 5 is a cross-sectional view illustrating an area in which the first ceiling surface 44 is provided. As illustrated in FIG. 5, at a periphery (a portion facing the outer edge of the vacuum vessel 1) of the fan-shaped projection A, an L-shaped bent portion 46 that faces an outer circumference of the rotary table 2 is formed. Similar to the projection A, the bent portion 46 suppresses entry of the raw material gas and the reactant gas from both sides of the separation region D, thereby preventing the raw material gas from mixing with the reactant gas. As the fan-shaped projection 4 is provided on the top plate 11 and the top plate 11 can be removed from the container body 12, there is a slight gap between the outer peripheral surface of the bent portion 46 and the container body 12. A clearance between the inner peripheral surface of the bent portion 46 and the outer end surface of the rotary table 2 and the gap between the outer peripheral surface of the bent portion 46 and the container body 12 is set to a dimension similar to, for example, the height of the first ceiling surface 44 relative to the upper surface of the rotary table 2.

In the separation region D, the inner peripheral wall of the container body 12 is formed vertically in proximity to the outer peripheral surface of the bent portion 46 (FIG. 4). However, in a portion other than the separation region D, for example, the inner peripheral wall is depressed outward from a position facing the outer end surface of the rotary table 2 to the bottom 14 (FIG. 1). A cross-sectional shape of the depressed portion is generally rectangular. Hereinafter, for the sake of explanation, the depressed portion is referred to as an exhaust region. Specifically, an exhaust region communicating with the first processing region P1 is referred to as a first exhaust region E1, and an exhaust region communicating with the second processing region P2 is referred to as a second exhaust region E2. At the bottom of the first exhaust region E1 and the second exhaust region E2, a first exhaust port 610 and a second exhaust port 620 are formed, respectively, as illustrated in FIGS. 1-3. The first exhaust port 610 and the second exhaust port 620 are respectively connected to vacuum pumps 640 and 641, which are examples of exhaust devices, via exhaust pipes 630 and 631, respectively, as illustrated in FIGS. 1 and 3. Also, a pressure controller 650 is provided in the exhaust pipe 630 connecting the vacuum pump 640 with the first exhaust port 610. Similarly, a pressure controller 651 is provided in the exhaust pipe 631 connecting the vacuum pump 641 with the second exhaust port 620. Accordingly, the deposition apparatus is configured such that exhaust pressure of the first exhaust port 610 and exhaust pressure of the second exhaust port 620 can be controlled independently. The pressure controllers 650 and 651 may be, for example, automatic pressure controllers. Also, the exhaust pipe 632 communicating with the gas exhaust section 36 is connected to a section of the exhaust pipe 630 between the pressure controller 650 and the vacuum pump 640. Thus, gas exhausted from the gas exhaust section 36 and gas exhausted from the first exhaust port 610 are evacuated by the common vacuum pump 640. However, the exhaust pipe 632 communicating with the gas exhaust section 36 may be connected to a vacuum evacuation means such as a vacuum pump, which is provided separately from the vacuum pump 640, without being connected to the exhaust pipe 630 communicating with the first exhaust port 610.

In a space between the rotary table 2 and the bottom 14 of the vacuum vessel 1, a heater unit 7 which is a heating means is provided, as illustrated in FIGS. 1 and 5. A wafer W on the rotary table 2 is heated to a temperature (e.g., 450° C.) determined by a process recipe, via the rotary table 2. An annular cover member 71 is provided below the periphery of the rotary table 2 (FIG. 5). The cover member 71 partitions an atmosphere from the upper space of the rotary table 2 to the first and second exhaust regions E1 and E2 and an atmosphere in which the heater unit 7 is disposed, to prevent gas from entering the lower area of the rotary table 2. The cover member 71 includes an inner member 71a and an outer member 71b. The inner member 71a is disposed below a periphery of the rotary table 2 such that an upper surface of the inner member 71a faces an outer circumference of the rotary table 2 or a space outside of the outer circumference of the rotary table 2. The outer member 71b is disposed between the inner member 71a and an inner wall surface of the vacuum vessel 1. The outer member 71b is provided below the bent portion 46 formed at the periphery of the projection 4 in the separation region D, and is in close proximity to the bent portion 46. The inner member 71a surrounds the heater unit 7 throughout below the outer circumference of the rotary table 2 (and below a slightly external side of the outer circumference of the rotary table 2).

In a vicinity of a center side of the lower surface of the rotary table 2, a portion of the bottom 14, which is positioned closer to the rotational center than the space in which the heater unit 7 is disposed, protrudes upward close to the core 21, to form a projection 12a. A space between the projection 12a and the core 21 is narrow, and a space between the rotating shaft 22 and an inner peripheral surface of a through-hole for the rotating shaft 22 passing through the bottom 14 is also narrow, which communicates with the casing 20. The casing 20 is provided with a purge gas supply line 72 for supplying Ar gas as a purge gas into a narrow space, in order to purge gases from the narrow space. Below the heater unit 7, multiple purge gas supply lines 73 are provided at the bottom 14 of the vacuum vessel 1 at predetermined angular intervals, to purge gases from the space in which the heater unit 7 is disposed (one purge gas supply line 73 is illustrated in FIG. 5). A lid member 7a is provided between the heater unit 7 and the rotary table 2 so as to cover a region from an inner peripheral wall of the outer member 71b (the upper surface of the inner member 71a) to an upper end of the projection 12a in a circumferential direction, in order to prevent gas from entering the area in which the heater unit 7 is disposed. The lid member 7a may be made of, for example, quartz.

A separation gas supply line 51 is connected to the center of the top plate 11 of the vacuum vessel 1, and is configured to supply Ar gas, which is the separation gas, to a space 52 between the top plate 11 and the core 21. The separation gas supplied to the space 52 is discharged toward the periphery along the surface of the rotary table 2 on a side in which a wafer placing region (i.e., a region for placing a wafer) is provided, through a narrow gap 50 between the protruding portion 5 and the rotary table 2. The gap 50 may be maintained at a pressure higher than the spaces 481 and 482 by the separation gas. Accordingly, the gap 50 prevents the raw material gas supplied to the first processing region P1 and the reactant gas supplied to the second processing region P2 from mixing through a central region C. That is, the gap 50 (or the central region C) functions similarly to the separation space H (or the separation region D).

As described above, a noble gas such as Ar or an inert gas such as N₂ (hereinafter collectively referred to as a “purge gas”) is supplied from above and below, via the separation gas supply line 51 and the purge gas supply line 72, to an axial side of the rotary table 2. If a flow rate of the raw material gas is set to a small flow rate, for example, 30 sccm or less, the raw material gas is affected by the Ar gas on the axial side, and concentration of the raw material gas is reduced on the axial side of the rotary table 2, thereby reducing in-plane uniformity of film thickness. In the deposition apparatus according to the present embodiment, the axial-side auxiliary gas supply section 33 is provided on the axial side to supply an auxiliary gas, thereby reducing the effect of a purge gas flowing out of the axial side without control, and appropriately controlling the concentration of the raw material gas. From this viewpoint, the axial-side auxiliary gas supply section 33 plays a more important role than the outer-side auxiliary gas supply section 35. Therefore, in another embodiment, the bottom plate 31 of the showerhead 30 of the deposition apparatus may be configured to include only the raw material gas supply section 32 and the axial-side auxiliary gas supply section 33. Even in such a configuration, decrease in film thickness on the axial side of the rotary table 2 can be prevented, and a sufficient effect can be obtained. However, in order to adjust the film thickness more accurately for a variety of processes, it is preferable that not only the axial-side auxiliary gas supply section 33 but also the intermediate auxiliary gas supply section 34 and the outer-side auxiliary gas supply section 35 are provided.

As illustrated in FIGS. 2 and 3, a conveying port 15 is formed on the side wall of the vacuum vessel 1 to pass a wafer (substrate) between an external conveying arm 10 and the rotary table 2. The conveying port 15 is opened and closed by a gate valve (not illustrated). When the recess 24, which is the wafer placing region in the rotary table 2, is moved to a position facing the conveying port 15, a wafer is passed between the recess 24 and the conveying arm 10. Therefore, below the rotary table 2, lift pins that lift the wafer W from the back surface by passing through the recess 24, and a lifting mechanism for the lift pins, are provided at a location at which the wafer W is passed between the recess 24 and the conveying arm 10 corresponding to the feeding position. Note that the lift pins and the lifting mechanism are not illustrated in the drawings.

In the deposition apparatus according to the present embodiment, as illustrated in FIG. 1, a controller 100 configured by a computer is provided. The controller 100 controls operation of an entirety of the deposition apparatus. A memory of the controller 100 stores a program to cause the deposition apparatus to perform a deposition method, which will be described below, under control of the controller 100. The program includes steps of causing the deposition method to perform the deposition method which will be described below. The program may be stored in a recording medium 102, such as a hard disk, a compact disc, a magneto-optical disc, a memory card, and a flexible disk, and may be installed in the controller 100 by loading the program stored in the recording medium 102 into the storage device 101 using a predetermined reading device.

Next, the configuration of the showerhead 30, including the bottom plate 31, in the deposition apparatus according to the present embodiment will be described in more detail.

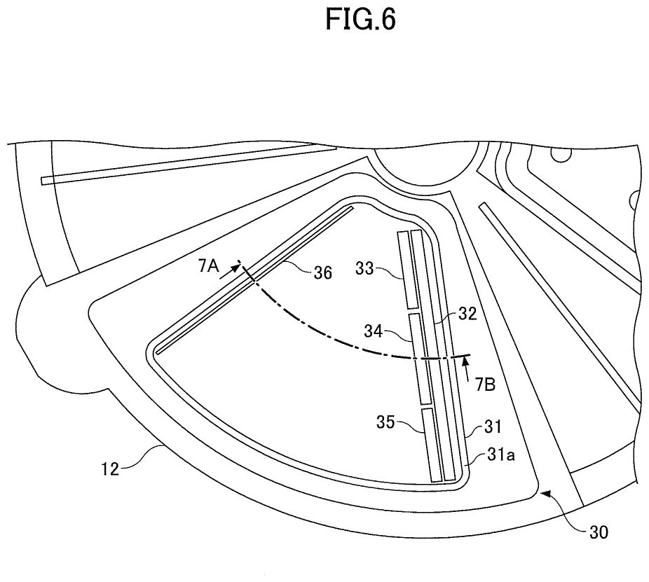

FIG. 6 is a top view of the showerhead 30 of the deposition apparatus of FIG. 1. As illustrated in FIG. 6, in the bottom plate 31, the raw material gas supply section 32, the axial-side auxiliary gas supply section 33, the intermediate auxiliary gas supply section 34, the outer-side auxiliary gas supply section 35, and the gas exhaust section 36 are formed. The bottom plate 31 is generally of a circular sector shape in a plan view of which the center of the circle is at the axial side of the rotary table 2.

The raw material gas supply section 32, the axial-side auxiliary gas supply section 33, the intermediate auxiliary gas supply section 34, and the outer-side auxiliary gas supply section 35 are provided, in a plan view, on the upstream side of the rotational direction of the rotary table 2, relative to the middle of the bottom plate 31 in the circumferential direction. The axial-side auxiliary gas supply section 33, the intermediate auxiliary gas supply section 34, and the outer-side auxiliary gas supply section 35 are provided at a position near the raw material gas supply section 32, so that concentration of the raw material gas supplied from the raw material gas supply section 32 can be adjusted. In the illustrated example, the axial-side auxiliary gas supply section 33, the intermediate auxiliary gas supply section 34, and the outer-side auxiliary gas supply section 35 are provided on the downstream side of the rotational direction of the rotary table 2, with respect to the raw material gas supply section 32.

The gas exhaust section 36 is provided, in a plan view, on the downstream side of the rotational direction of the rotary table 2, relative to the middle of the bottom plate 31 in the circumferential direction. That is, the gas exhaust section 36 is provided on the downstream side of the rotational direction of the rotary table 2 with respect to the axial-side auxiliary gas supply section 33, the intermediate auxiliary gas supply section 34, and the outer-side auxiliary gas supply section 35.

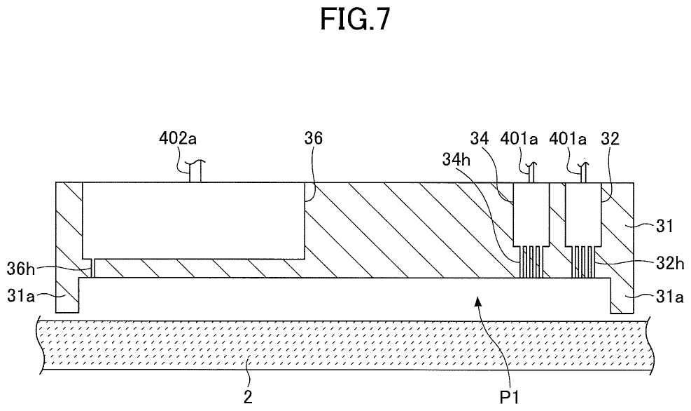

FIG. 7 is a cross-sectional view of the showerhead 30 of the deposition apparatus of FIG. 1, and illustrates a cross-section that is cut along the dashed-dotted arc 7A-7B in FIG. 6. As illustrated in FIG. 7, the raw material gas supply section 32 includes the multiple gas discharge holes 32h, and discharges a raw material gas from the multiple gas discharge holes 32h to the first processing region P1. The intermediate auxiliary gas supply section 34 includes the multiple gas discharge holes 34h, and discharges an auxiliary gas from the multiple gas discharge holes 34h to the first processing region P1. Although not illustrated in the drawings, each of the axial-side auxiliary gas supply section 33 and the outer-side auxiliary gas supply section 35 also includes multiple gas discharge holes similar to the intermediate auxiliary gas supply section 34, and the axial-side auxiliary gas supply section 33 and the outer-side auxiliary gas supply section 35 discharge the auxiliary gas from their respective multiple gas discharge holes to the first processing region P1. Further, the gas exhaust section 36 includes the gas exhaust holes 36h, and the raw material gas and the auxiliary gas that are discharged to the first processing region P1 are exhausted from the gas exhaust holes 36h.

Further, as illustrated in FIG. 7, the outer boundary of the lower surface of the bottom plate 31 is provided with a protrusion 31a that protrudes downward (toward the rotary table 2) throughout the boundary. The lower surface of the protrusion 31a is close to the upper surface of the rotary table 2, and the first processing region P1 is defined above the rotary table 2 by the protrusion 31a, the upper surface of the rotary table 2, and the lower surface of the bottom plate 31. The distance between the lower surface of the protrusion 31a and the upper surface of the rotary table 2 may be approximately the same as the height hi of the first ceiling surface 44 in the separation space H (FIG. 4) with respect to the upper surface of the rotary table 2.

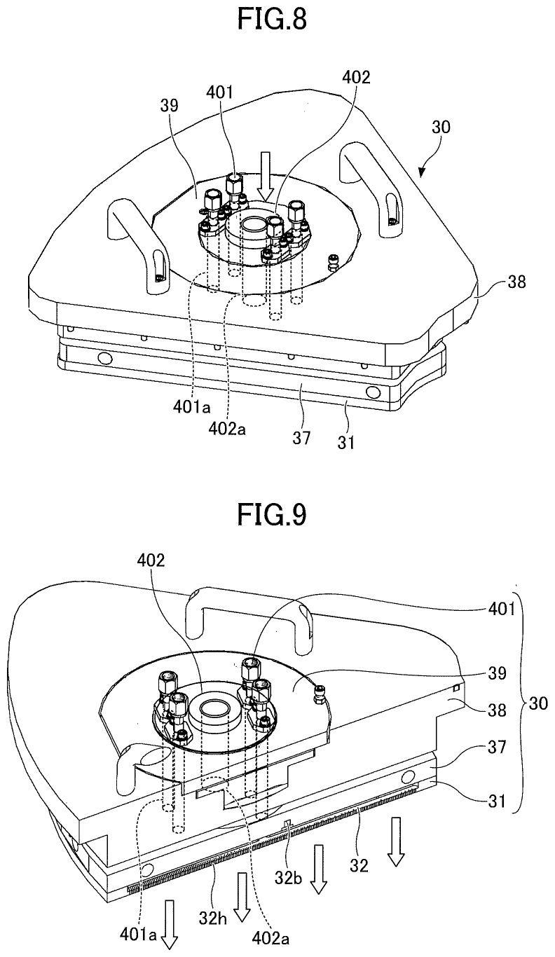

FIG. 8 is a perspective view illustrating an example of the overall configuration of the showerhead 30. As illustrated in FIG. 8, the showerhead 30 includes the bottom plate 31, a middle section 37, an upper section 38, a central section 39, and gas inlets 401. The showerhead 30, including the bottom plate 31, may be formed of a metallic material such as aluminum.

The gas inlets 401 are provided to introduce a raw material gas and an auxiliary gas from the outside, and each of the gas inlets 401 is configured, for example, as a connector. For each of the four gas supply sections (the raw material gas supply section 32, the axial-side auxiliary gas supply section 33, the intermediate auxiliary gas supply section 34, and the outer-side auxiliary gas supply section 35), the gas inlet 401 is provided individually. Thus, each of the four gas supply sections is configured to supply gas individually. Below the gas inlets 401, respective gas introduction passages 401a of the gas inlets 401 are formed, and the raw material gas supply section 32, the axial-side auxiliary gas supply section 33, the intermediate auxiliary gas supply section 34, and the outer-side auxiliary gas supply section 35 are directly connected to their respective gas introduction passages 401a of the gas inlets 401.

A gas outlet 402 is provided to expel gas, such as a raw material gas and an auxiliary gas, to the outside, and is configured, for example, as a connector. The gas outlet 402 is provided corresponding to the gas exhaust section 36. Below the gas outlet 402, a gas exhaust passage 402a is formed, and the gas exhaust passage 402a is directly connected to the gas exhaust section 36.

The central section 39 includes the gas inlets 401, the gas introduction passages 401a, the gas outlet 402, and the gas exhaust passage 402a, and is configured to be rotatable. Thus, the angle of the showerhead 30 can be adjusted and the positions of the raw material gas supply section 32, the axial-side auxiliary gas supply section 33, the intermediate auxiliary gas supply section 34, the outer-side auxiliary gas supply section 35, and the gas exhaust section 36 can be finely adjusted in accordance with processes.

The upper section 38 serves as an upper frame, and can be installed in the top plate 11. The middle section 37 serves to connect the upper section 38 and the bottom plate 31.

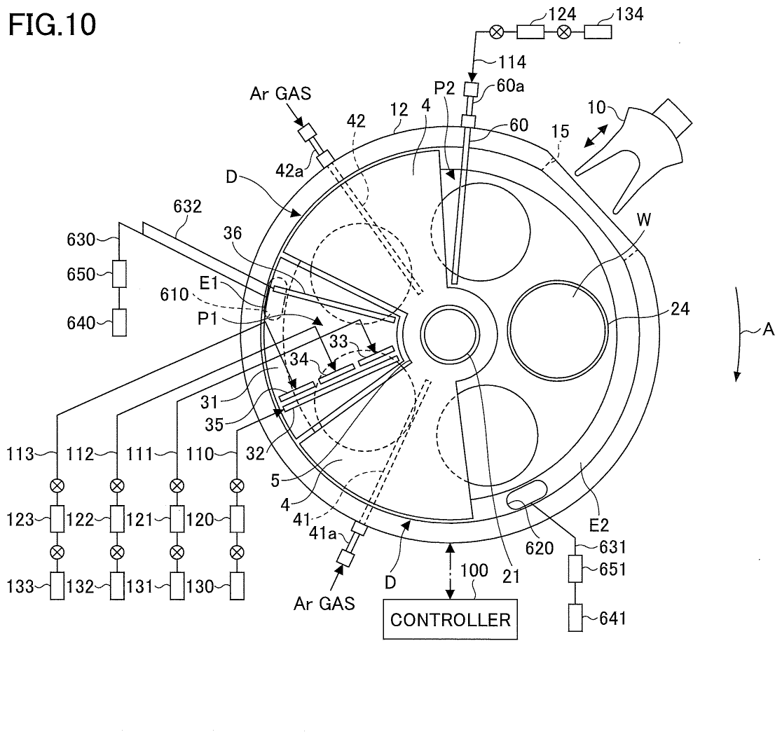

FIG. 9 is a cross-sectional perspective view of the showerhead 30 cut along the raw material gas supply section 32. As illustrated in FIG. 9, a raw material gas supplied from one of the gas inlets 401 is supplied to the raw material gas supply section 32 via a gas supply passage 32b formed in the middle section 37, and the raw material gas is supplied from the gas discharge holes 32h like a shower.

### (Deposition Method)

A film deposition method (may also be referred to as a “deposition method”) according to the first embodiment will be described with reference to an example in which the above-described deposition apparatus is used. Thus, embodiments will be described, as appropriate, with reference to the drawings described above.

First, the gate valve is opened, and the conveying arm 10 passes a wafer W from the outside to the recess 24 of the rotary table 2 through the conveying port 15. The wafer W is passed by raising and lowering the lift pins from the bottom side of the vacuum vessel 1, through the through-holes in the bottom surface of the recess 24 when the recess 24 stops at a position facing the conveying port 15. The above-described passing operations of wafers W are repeatedly performed while rotating the rotary table 2 intermittently, to place the wafers W into the five recesses 24 of the rotary table 2.

Next, the gate valve is closed and the vacuum vessel 1 is evacuated to the minimum attainable degree of vacuum, by the vacuum pumps 640 and 641. Thereafter, Ar gas as a separation gas is discharged from the separation gas nozzles 41 and 42 at a predetermined flow rate, and the Ar gas is discharged from the separation gas supply line 51 and the purge gas supply lines 72 and 73 at a predetermined flow rate. Also, by the pressure controllers 650, 651, and 652, the interior of the vacuum vessel 1 is adjusted to a preset processing pressure, and the exhaust pressure in the first exhaust port 610, the second exhaust port 620, and the gas exhaust section 36 are set to be at an appropriate differential pressure. As described above, the appropriate pressure difference is set according to the pressure set in the vacuum vessel 1.

Subsequently, the wafer W is heated to, for example, 400° C. by the heater unit 7 while rotating the rotary table 2 clockwise at rotating speed of, for example, 5 rpm.

Next, a raw material gas such as Si-containing gas and a reactant gas such as O₂ gas (oxidant gas) are discharged from the showerhead 30 and the processing gas nozzle 60, respectively. At this time from the raw material gas supply section 32 of the showerhead 30, the Si-containing gas is supplied together with a carrier gas such as Ar. However, from the axial-side auxiliary gas supply section 33, the intermediate auxiliary gas supply section 34, and the outer-side auxiliary gas supply section 35, only the carrier gas such as Ar gas may be supplied. Alternatively, from the axial-side auxiliary gas supply section 33, the intermediate auxiliary gas supply section 34, and the outer-side auxiliary gas supply section 35, a mixed gas of Si-containing gas and Ar gas, with a different mixture ratio from the raw material gas supplied from the raw material gas supply section 32, may be supplied. Thus, the concentration of the raw material gas at the axial side, the intermediate position, and the outer circumferential side can be adjusted, and in-plane uniformity can be increased. Further, if the axial-side auxiliary gas supply section 33, the intermediate auxiliary gas supply section 34, and the outer-side auxiliary gas supply section 35 are configured such that the distance from the rotary table 2 to the axial-side auxiliary gas supply section 33, the intermediate auxiliary gas supply section 34, and the outer-side auxiliary gas supply section 35 is greater than the distance from the rotary table 2 to the raw material gas supply section 32, flow of the raw material gas supplied from the raw material gas supply section 32 is not disturbed. The flow rate of the raw material gas may be set to be 30 sccm or less, for example, 10 sccm. Further, as described above, only the axial-side auxiliary gas supply section 33 may be provided and only an axial-side auxiliary gas may be supplied as the auxiliary gas.

Then, while the rotary table 2 rotates once, a silicon oxide film is formed on the wafer W in the following manner. That is, when the wafer W passes through the first processing region P1 below the bottom plate 31 of the showerhead 30, the Si-containing gas is adsorbed on the surface of the wafer W. Next, as the wafer W passes through the second processing region P2 below the processing gas nozzle 60, the Si-containing gas on the wafer W is oxidized by O₃ gas from the processing gas nozzle 60, and a single molecular layer (or several molecular layers) of silicon oxide is formed.

After rotating the rotary table 2 by the number of times a silicon oxide film having a desired film thickness is formed, the deposition process is terminated by stopping supply of the Si-containing gas, the auxiliary gas, and O₂ gas. Subsequently, the supply of Ar gas from the separation gas nozzles 41 and 42, the separation gas supply line 51, and the purge gas supply lines 72 and 73 is also stopped, and the rotation of the rotary table 2 is stopped. Thereafter, the wafers W are unloaded from the vacuum vessel 1 by performing the reverse procedure when the wafers W are loaded into the vacuum vessel 1.

Incidentally, although a case of using a silicon-containing gas as the raw material gas and using an oxidant gas as the reactant gas has been described in the present embodiment, various combinations of the raw material gas and the reactant gas can be used. For example, by using a silicon-containing gas as the raw material gas and using a nitriding gas such as ammonia as the reactant gas, a silicon nitride film may be formed. In addition, by using a titanium-containing gas as the raw material gas and using a nitriding gas as the reactant gas, a titanium nitride film may be formed. Thus, a variety of gases, such as organometallic gases, can be used as the raw material gas, and various types of gas that can produce a reaction product by reacting with the raw material gas may be used as the reactant gas, such as oxidant gas and nitride gas.

### Second Embodiment

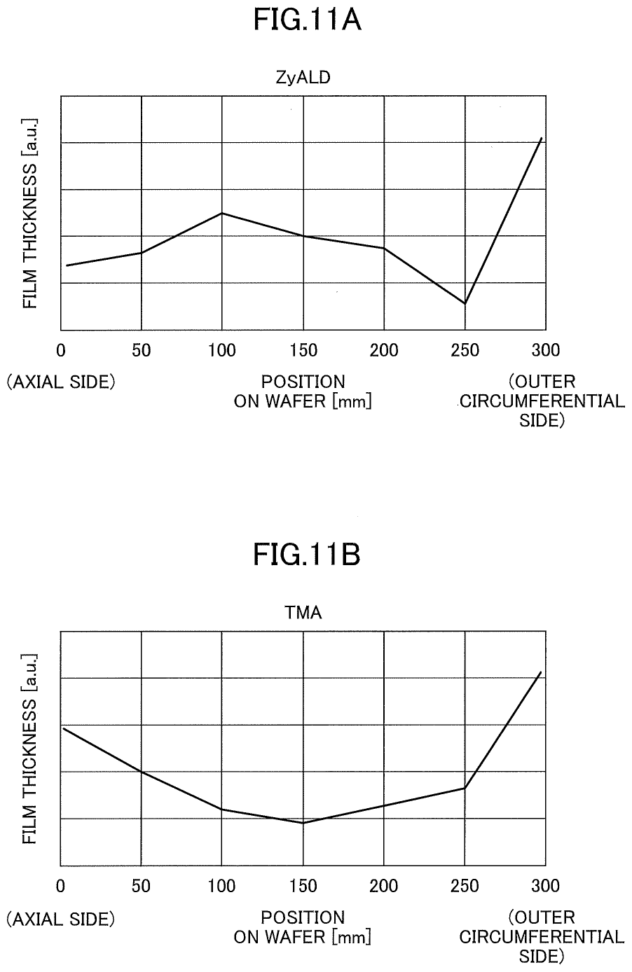

A deposition apparatus according to a second embodiment will be described. FIG. 10 is a cross-sectional view illustrating an example of the configuration of the deposition apparatus according to the second embodiment.

As illustrated in FIG. 10, the deposition apparatus of the second embodiment differs from the deposition apparatus of the first embodiment in that the gas exhaust section 36 is connected to a section of the exhaust pipe 630 between the first exhaust port 610 and the pressure controller 652 via the exhaust pipe 632. As the other configurations are the same as those of the deposition apparatus according to the first embodiment, the description thereof will be omitted.

Thus, according to the deposition apparatus of the second embodiment, the exhaust pressure of a gas exhausted from the gas exhaust section 36 and the exhaust pressure of a gas exhausted from the first exhaust port 610 are controlled by the common pressure controller 650, and the gas exhausted from the gas exhaust section 36 and the gas exhausted from the first exhaust port 610 are exhausted by the common vacuum pump 640. This eliminates the need for a dedicated pressure controller and a dedicated vacuum pump for the gas exhaust section 36, and thus reduces the installation cost.

FIG. 10 illustrates a case in which the exhaust pipe 632 connected to the gas exhaust section 36 is connected to the exhaust pipe 630 outside the vacuum vessel 1, but is not limited thereto. For example, the gas exhaust section 36 and the first exhaust port 610 may be connected inside the vacuum vessel 1.

### [Relationship Between Gas Type and Film Thickness Distribution]

Results of experiments in which the relationship between gas species and film thickness distribution when the film deposition process is performed using the deposition apparatus according to the first embodiment will be described. In the experiments, a silicon oxide film was deposited on a wafer W using either ZyALD (registered trademark), trimethylaluminum (TMA), or tris(diraethyiamino)silane (3DMAS), as a raw material gas supplied from the raw material gas supply section 32. In addition, gas was not supplied from the auxiliary gas supply section. The process conditions in the experiments are as follows.

### (Process Conditions)

Wafer W temperature: 300° C.
Pressure in the vacuum vessel 1: 266 Pa
Rotating speed of table 2: 3 rpm
Raw material gas from the raw material gas supply section 32: ZyALD (TMA), TMA, or 3DMAS
Oxidant gas from the processing gas nozzle 60: O₃/O₂

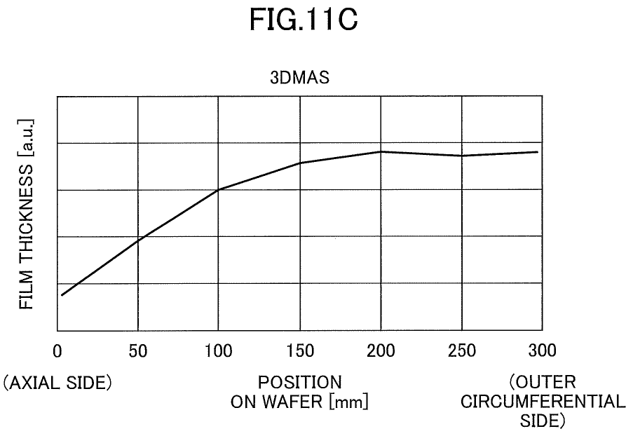

FIGS. 11A to 11C are diagrams for explaining film thickness distribution for each gas species. FIG. 11A illustrates a result when ZyALD (registered trademark) was used as the raw material gas, FIG. 11B illustrates a result when TMA was used as the raw material gas, and FIG. 11C illustrates a result when 3DMAS was used as the raw material gas. In FIGS. 11A to 11C, the horizontal axis indicates a position on a wafer (mm). A position on the wafer closest to the axis of the rotary table 2 is 0 mm, and a position on the wafer closest to the outer circumference of the rotary table 2 is 300 mm. The vertical axis indicates the thickness of the silicon oxide film (a.u.).

As illustrated in FIG. 11A, when ZyALD (registered trademark) was used as the raw material gas, it can be seen that a substantially uniform film thickness was obtained in the position on a wafer of 0 mm to 250 mm, but the film thickness was thickened at the outer circumferential side of the rotary table 2.

As illustrated in FIG. 11B, when TMA was used as the raw material gas, the film thickness decreased from the axial side (position of 0 mm) to the intermediate position (position of 150 mm), and the film thickness increased from the intermediate position (position of 150 mm) to the outer circumferential side (position of 300 mm).

As illustrated in FIG. 11C, when 3DMAS was used as the raw material gas, the film thickness increased from the axial side (position of 0 mm) toward the outer circumferential side (position of 300 mm).

As described above, it can be seen that in-plane distribution of the film thickness varies depending on the type of the raw material gas used. The in-plane distribution of the film thickness can be adjusted by, for example, changing the design (e.g., shape, arrangement) of the raw material gas supply section 32 of the showerhead 30. However, if the raw material gas supply section 32 is designed so as to be suitable for one specific gas, variations in film thickness may occur when other gases are used.

In the deposition apparatus according to the present embodiment, multiple auxiliary gas supply sections are provided at a downstream side of the rotational direction of the rotary table 2 with respect to the raw material gas supply section 32, and the gas exhaust section 36 is provided at a downstream side of the rotational direction of the rotary table 2 with respect to the multiple auxiliary gas supply sections. Accordingly, by adjusting the flow rate of an auxiliary gas supplied from each of the multiple auxiliary gas supply sections individually, the flow of the raw material gas supplied from the raw material gas supply section 32 can be controlled to adjust film deposition speed on the plane of the wafer W. Therefore, the in-plane distribution of the film thickness can be adjusted with high accuracy. Details will be described below.

In addition, according to the deposition apparatus of the present embodiment, as the in-plane distribution of the film thickness can be adjusted with high accuracy for each film species, when multiple types of films are successively deposited using the single deposition apparatus, desired in-plane distribution of the film thickness can be obtained for each film species.

### <Simulation Results>

Results of simulation experiments, in which the film formation method according to the present, embodiment was performed using the deposition apparatus according to the present embodiment, will be described. For ease of understanding, components corresponding to the components described in the aforementioned embodiments are given the same reference numerals, and the description thereof is omitted.

The deposition apparatus used in the simulation experiments has the same configuration as the deposition apparatus described in the above-described first embodiment, which is a deposition apparatus equipped with a showerhead 30 including a raw material gas supply section 32 and an auxiliary gas supply section. Five auxiliary gas supply sections S1, S2, S3, S4, and S5 are provided in the auxiliary gas supply section, from the axial side of the auxiliary gas supply section to the outer circumferential side of the auxiliary gas supply section.

In the simulation experiment 1-1, paths of raw material gas flows in the first processing region P1, when a deposition process was performed under the following simulation condition 1-1, were analyzed.

### (Simulation Condition 1-1)

Pressure in vacuum vessel 1: 266 Pa
Exhaust pressure in the first exhaust, port 610: 266 Pa
Exhaust pressure in the second exhaust port 620: 266 Pa
Exhaust flow rate of the gas exhaust section 36: 1.176×10⁻⁵ kg/s (60% of the total flow rate of the raw material area)
Wafer W temperature: 300° C.
Rotating speed of the rotary table 2: 3 rpm
Raw material gas from the raw material gas supply section 32: ZyALD (registered trademark) (Ar: 450 sccm*ZyALD: 29 sccm)
Auxiliary gas from the auxiliary gas supply sections S1 to S5: No auxiliary gas
Oxidant gas from the processing gas nozzle 60: O₂ (10 slm)/O₂ (300 g/Nm;)
Separation gas from the separation gas nozzles 41 and 42: N₂ gas (5000 sccm)
Separation gas from the separation gas supply line 51: N₂ gas (5000 sccm)
Purge gas from the purge gas supply line 72: N₂ gas (5000 sccm)

In the simulation experiment 1-2, paths of raw material gas flows in the first processing region P1, when a deposition process was performed under the simulation condition 1-2 that is the same as the simulation condition 1-1 except that, the showerhead 30 does not have the gas exhaust section 36, were analyzed.

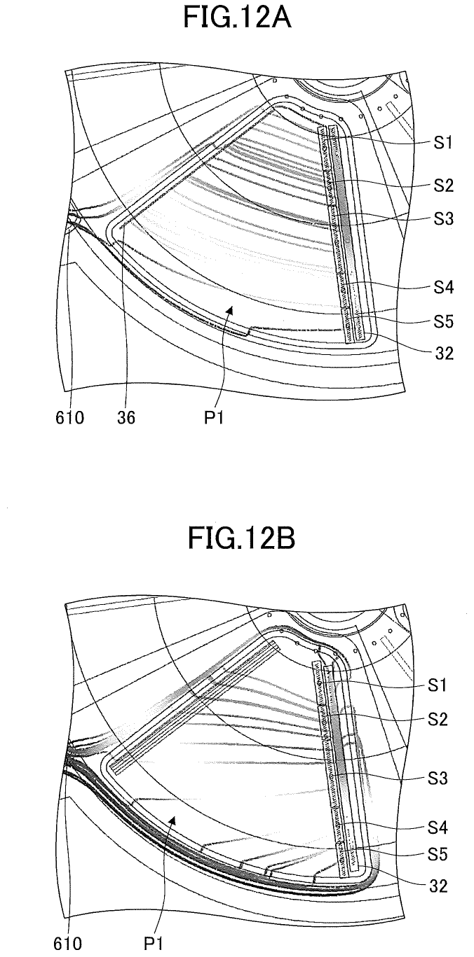

FIGS. 12A and 12B are diagrams illustrating the results of the analysis of the flow paths of the raw material gas in the simulation experiments 1-1 and 1-2, respectively. FIG. 12A illustrates the results of the analysis of the raw material gas flow paths in the simulation experiment 1-1, and FIG. 12B illustrates the result of the analysis of the raw material gas flow paths in the simulation experiment 1-2.

As illustrated in FIG. 12A, in the simulation experiment 1-1, it can be seen that the raw material gas from the raw material gas supply section 32 flows in the circumferential direction of the rotary table 2 toward the gas exhaust section 36 and that the raw material gas is supplied substantially uniformly in the radial direction of the rotary table 2.

In contrast, as illustrated in FIG. 12B, in the simulation experiment 1-2, it is seen that part of the raw material gas from the raw material gas supply section 32 flows in the upstream direction of the rotational direction of the rotary table 2, and then flows along the periphery of the showerhead 30. Because the raw material gas flowing around the showerhead 30 makes little contribution to film deposition, utilization efficiency of the raw material gas decreases. Further, the other part of the raw material gas from the raw material gas supply section 32 flows in the direction of the first exhaust port 610, but tends to flow toward the outer peripheral side of the rotary table 2. Thus, it can be seen that the raw material gas is not supplied substantially uniformly in the radial direction of the rotary table 2.

As described above, in a case in which the deposition process is performed using the deposition apparatus according to the present embodiment, it is considered that distribution of the raw material gas becomes uniform and that in-plane uniformity of the film thickness is improved. Also, utilization efficiency of the raw material gas is improved.

In the simulation experiment 2-1, the deposition process was performed under the following simulation condition 2-1. In addition, a mole fraction difference of zirconium (Zr) at each position on the rotary table 2 in the radial direction was analyzed. Note that, in the present specification, a position on the rotary table 2 in the radial direction may be referred to as a “Y-Line”.

### (Simulation Condition 2-1)

Pressure in the vacuum vessel 1: 266 Pa
Exhaust pressure in the first exhaust port 610: 266 Pa
Exhaust pressure in the second exhaust port 620: 266 Pa
Exhaust flow rate of the gas exhaust section 36: 1.214×10⁻⁷ kg/s (60% of the total flow rate of the raw material area)
Wafer W temperature: 300+ C.
Rotating speed of the rotary table 2: 3 rpm
Raw material gas from the raw material gas supply section 32: ZyALD (registered trademark) (Ar: 450 sccm+ZyALD: 29 sccm)
Auxiliary gas from the auxiliary gas supply section S1: N₂ gas (30 sccm)
Auxiliary gas from the auxiliary gas supply sections S2 to S5: No auxiliary gas
Oxidant gas from the processing gas nozzle 60: O₂ (10 slm)/O₂ (300 g/Nm⁻³)
Separation gas from the separation gas nozzles 41 and 42: N₂ gas (5000 sccm)
Separation gas from the separation gas supply line 51: N₂ gas (5000 sccm)
Purge gas from the purge gas supply line 72: N₂ gas (5000 sccm)

In the simulation experiment 2-2, the deposition process was performed under the same simulation conditions as that in the simulation experiment 2-1, except that the showerhead 30 does not include the gas exhaust section 36. In addition, the mole fraction difference of Zr at each position on the Y-Line was analyzed.

In the simulation experiment 3-1, a deposition process was performed under the same simulation condition as that in the simulation experiment 2-1, except that N₂ gas was supplied at 30 seem from the auxiliary gas supply section S2 instead of the auxiliary gas supply section S1. In addition, the mole fraction difference of Zr at each position on the Y-Line was analyzed.

In the simulation experiment 3-2, a deposition process was performed under the same simulation condition as that in the simulation experiment 3-1, except that the showerhead 30 does not have the gas exhaust section 36. In addition, the mole fraction difference of Zr at each position on the Y-Line was analyzed.

In the simulation experiment 4-1, a deposition process was performed under the same simulation conditions as that in the simulation experiment 2-1 except that gas was supplied at 30 sccm from the auxiliary gas supply section S3 instead of the auxiliary gas supply section S1. In addition, the mole fraction difference of Zr at each position on the Y-Line was analyzed.

In the simulation experiment 4-2, a deposition process was performed under the same simulation conditions as that in the simulation experiment 4-1 except that the showerhead 30 does not have the gas exhaust section 36. In addition, the mole fraction difference of Zr at each position on the Y-Line was analyzed.

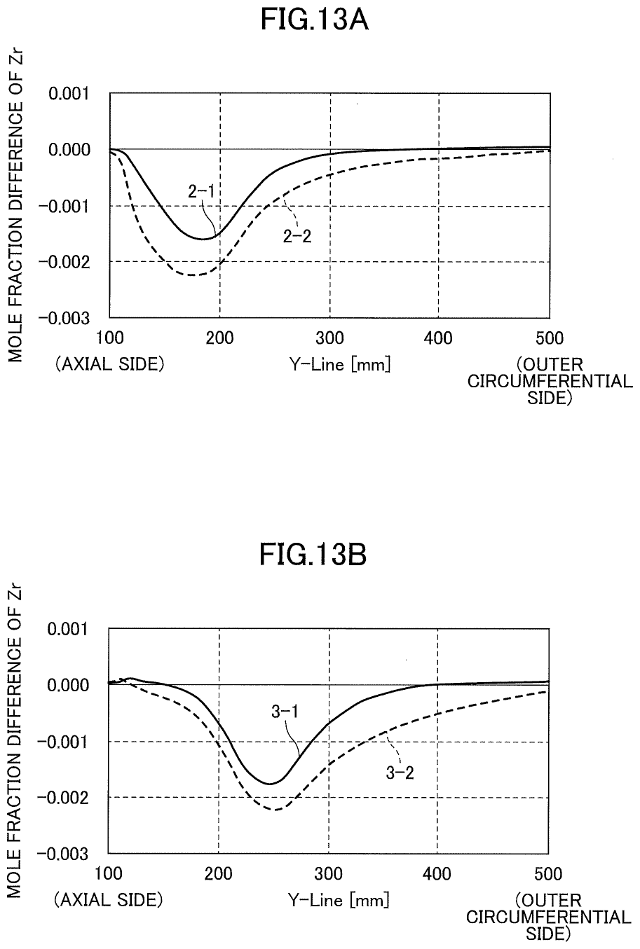

FIGS. 13A to 13C are diagrams illustrating the results of the analysis of the simulation experiments 2-1, 2-2, 3-1, 3-2, 4-1, and 4-2. FIG. 13A illustrates the results of the analysis of the simulation experiments 2-1 and 2-2, FIG. 13B illustrates the results of the analysis of the simulation experiments 3-1 and 3-2, and FIG. 13C illustrates the results of the analysis of the simulation experiments 4-1 and 4-2. In FIGS. 13A to 13C, the horizontal axis indicates the Y-Line [mm], and the vertical axis indicates the mole fraction difference of Zr. Note that the mole fraction difference of Zr is a value obtained by subtracting the mole fraction of Zr in a case in which the auxiliary gas is not supplied from the mole fraction of Zr in a case in which the auxiliary gas is supplied. In FIGS. 13A to '13C, solid curves indicate the results of the analysis of the simulation experiments 2-1, 3-1, and 4-1, and dashed curves indicate the results of the analysis of the simulation experiments 2-2, 3-2, and 4-2.

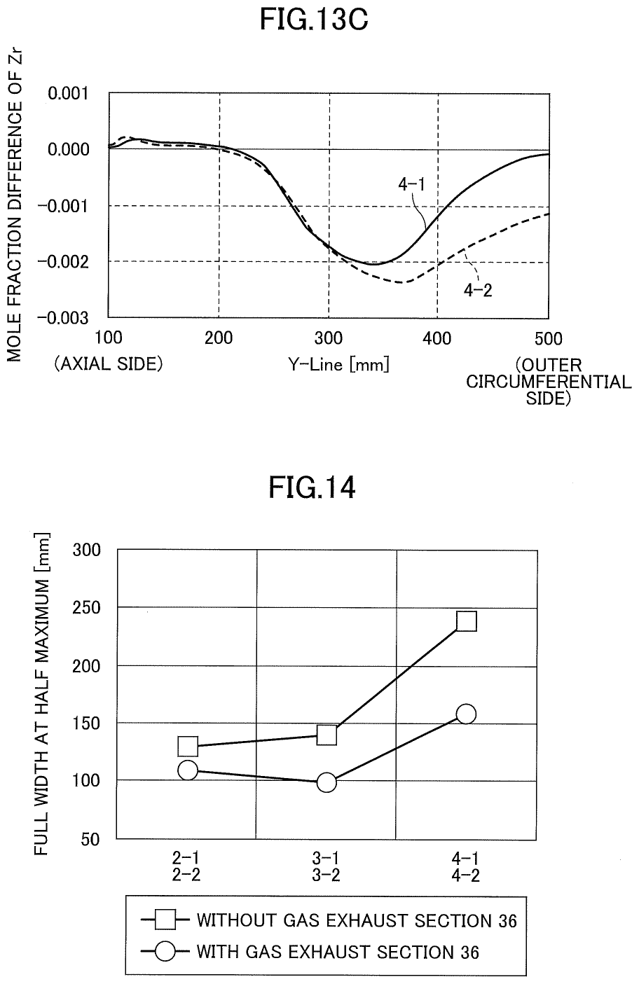

FIG. 14 is a diagram illustrating the results of the analysis of the simulation experiments 2-1, 2-2, 3-1, 3-2, 4-1, and 4-2, which illustrates the full width at half maximum (mm) of each waveform illustrated in FIGS. 13A to 13C.

As illustrated in FIGS. 13A to 13C, it can be seen that a position on the rotary table 2 in the radial direction in which the mole fraction difference of Zr becomes small is shifted in accordance with a position where the auxiliary gas is supplied. Specifically, as illustrated in FIG. 13A, in a case in which the auxiliary gas is supplied from the auxiliary gas supply section S1, the mole fraction difference of Zr becomes small at a position close to the axis of the rotary table 2 corresponding to the position where the auxiliary gas is supplied (hereinafter, the position may be referred to as a “first position”). In addition, as illustrated in FIG. 13B, in a case in which the auxiliary gas is supplied from the auxiliary gas supply section S2, the mole fraction difference of Zr becomes small at a position outside the first position (hereinafter, the position outside the first position may be referred to as a “second position”). In addition, as illustrated in FIG. 13C, in a case in which the auxiliary gas is supplied from the auxiliary gas supply section S3, the mole fraction difference of Zr becomes small at a position outside the second position.

In addition, as illustrated in FIGS. 13A to 13C and FIG. 14, by exhausting gas from the gas exhaust section 36, the full width of half maximum of the mole fraction difference of Zr is reduced, compared to a case in which gas is not exhausted from the gas exhaust section 36. Therefore, it can be said that controllability of the feed amount of raw material in the radial direction of the rotary table 2 is improved by exhausting gas from the gas exhaust section 36.

As described above, it is considered that by performing the deposition process using the deposition apparatus according to the present embodiment, the feed amount of raw material can be adjusted with high accuracy in the radial direction of the rotary table 2, and the in-plane distribution of the film thickness can be adjusted with high accuracy.

The embodiments described herein should be considered to be exemplary in all respects and not restrictive. The above embodiments may be omitted, substituted, or modified in various forms without departing from the appended claims and spirit thereof.

What is claimed is:

1. A deposition apparatus comprising:
a processing chamber;
a rotary table provided in the processing chamber, an upper surface of the rotary table including a substrate placing region in which substrates are placed in a circumferential direction of the rotary table;
a raw material gas supply section provided above the rotary table, the raw material gas supply section extending in a radial direction of the rotary table;
a plurality of auxiliary gas supply sections provided, above the rotary table, on a downstream side of a rotational direction of the rotary table with respect to the raw material gas supply section, the plurality of auxiliary gas supply sections being arranged along the radial direction of the rotary table; and
a gas exhaust section provided, above the rotary table, on the downstream side of the rotational direction of the rotary table with respect to the plurality of auxiliary gas supply sections, the gas exhaust section extending in the radial direction of the rotary table.

2. The deposition apparatus according to claim 1, further comprising a showerhead; wherein the showerhead includes the raw material gas supply section, the plurality of auxiliary gas supply sections, and the gas exhaust section.

3. The deposition apparatus according to claim 2, wherein
the showerhead is generally of a circular sector shape in a plan view, and the showerhead is provided above the rotary table, so as to cover a part of the rotary table in the circumferential direction in the plan view.

4. The deposition apparatus according to claim 2, wherein the gas exhaust section includes one or more gas exhaust holes, and the gas exhaust holes are provided at a bottom surface of the showerhead along the radial direction of the rotary table.

5. The deposition apparatus according to claim 4, wherein the one or more gas exhaust holes are provided, in the bottom surface of the showerhead, on the downstream side of the rotational direction of the rotary table.

6. The deposition apparatus according to claim 2, further comprising an exhaust port provided at a location outside a circumference of the rotary table.

7. The deposition apparatus according to claim 6, wherein the deposition apparatus is configured such that exhaust pressure of the gas exhaust section and exhaust pressure of the exhaust port can be controlled independently.

8. The deposition apparatus according to claim 6, wherein the deposition apparatus is configured such that exhaust pressure of the gas exhaust section can be controlled in common with exhaust pressure of the exhaust port.

9. The deposition apparatus according to claim 2, wherein the raw material gas supply section and the plurality of auxiliary gas supply sections are provided with a plurality of gas discharge holes at a bottom surface of the showerhead; and
in each of the raw material gas supply section and the plurality of auxiliary gas supply sections, the plurality of gas discharge holes are arranged linearly along the radial direction of the rotary table.

10. The deposition apparatus according to claim 9, wherein the plurality of gas discharge holes are provided, in the bottom surface of the showerhead, on an upstream side of the rotational direction of the rotary table.

11. The deposition apparatus according to claim 1, wherein the deposition apparatus is configured to independently control a flow rate and composition of gas supplied to each of the raw material gas supply section and the plurality of auxiliary gas supply sections.

12. The deposition apparatus according to claim 1, wherein the raw material gas supply section is connected to at least a gas supply source of a raw material gas, and the plurality of auxiliary gas supply sections are connected to at least a gas supply source of an inert gas.

13. The deposition apparatus according to claim 1, wherein a raw material gas supplied from the raw material gas supply section is a silicon-containing gas, and an auxiliary gas supplied from the plurality of auxiliary gas supply sections is a gas for adjusting film thickness.

14. A method of depositing a film on a substrate placed on a rotary table provided in a processing chamber, the rotary table including a raw material gas supply region in a part of the rotary table in a circumferential direction of the rotary table, the method comprising:
supplying, in the raw material gas supply region, a raw material gas from a raw material gas supply section while rotating the rotary table, the raw material gas supply section being provided above the rotary table and extending in a radial, direction of the rotary table;
supplying, in the raw material gas supply region, an auxiliary gas from at least one of a plurality of auxiliary gas supply sections while rotating the rotary table, the plurality of auxiliary gas supply sections being provided, above the rotary table, on a downstream side of a rotational direction of the rotary table with respect to the raw material gas supply section, and being arranged along the radial direction of the rotary table; and
exhausting a gas in the raw material gas supply region from a gas exhaust section while rotating the rotary table, the gas exhaust section being provided, above the rotary table, on the downstream side of the rotational direction of the rotary table with respect to the plurality of auxiliary gas supply sections, and extending in the radial direction of the rotary table.
